(19) United States
(12) Patent Application Publication
(10) Pub. No.: US 2003/0107366 A1
(43) Pub. Date: Jun. 12, 2003

(54) Sensor with off-axis magnet calibration

(76) Inventors: Nicholas F. Busch, Freeport, IL (US); Joseph K. Murdock, Freeport, IL (US)

Correspondence Address: HONEYWELL INTERNATIONAL INC., 101 COLUMBIA ROAD, P O BOX 2245, MORRISTOWN, NJ, 07962-2245, US

(21) Appl. No.: 10/006,108

(22) Filed: Dec. 6, 2001

(51) Int. Cl. G01R 35/00

(52) U.S. Cl. 324/202; 324/207.2; 324/207.21; 324/224; 324/225; 324/207.12

(57) ABSTRACT

A method and system for calibrating a magnetic sensor having at least one magnet and at least one sensing element incorporated therein is disclosed. A magnetization direction of a magnet is altered in at least one axis until a sensing element is balanced. The magnet can be calibrated separately from the electronic components associated with the magnetic sensor to thereby achieve an improved calibration over temperature variations associated with the magnetic sensor. The magnetic sensor can be configured to include one or more magnets and one or more sensing elements. Such magnets may be calibrated according to the methods and systems disclosed herein, in association with such sensing elements. Each magnet may be calibrated separately from the electronics associated with the magnetic sensor. The magnetization direction of the magnet may be altered in one or more axis until the sensing element is balanced. The magnetic sensor may, for example, comprise a gear tooth sensor or a wheelspeed sensor.

### TECHNICAL FIELD

The present invention is generally related to magnetic sensors. The present invention is also related to magnetic sensors that utilize magnetically-sensitive components in combination with a permanent magnet to sense the presence or absence of a ferromagnetic object in a detection zone. The present invention is additionally related to gear tooth sensors and wheelspeed sensors. The present invention is also related to methods and systems for calibrating magnetic sensors, such as gear tooth sensors or wheelspeed sensors.

### BACKGROUND OF THE INVENTION

Many different types of magnetic sensors are known to those skilled in the art. Certain magnetic sensors utilize a permanent magnet to provide a bias magnetic field that is distorted when a ferromagnetic object moves through a pre-selected detection zone. The distortion of the magnetic field is sensed by a magnetically-sensitive component, which provides an output signal that changes to indicate the presence or absence of the ferromagnetic object within the detection zone. A common application of this type of sensor is a gear tooth sensor, which is utilized in automotive applications. Sensors of this type can be used in the timing apparatus of an automobile engine and, alternatively, in association with automatic or anti-lock braking systems.

Several features of magnetic sensors are important. The sensor must be able to be calibrated accurately so that the output signals from a magnetically-sensitive component precisely correspond to the passage of ferromagnetic teeth through the detection zone of the sensor. Additionally, it is desirable to manufacture the magnetic sensor so that its overall size and number of components are minimized and its total cost is reduced. The magnetically-sensitive components utilized in magnetic sensors can comprise magnetoresistors, Hall effect elements, or other magnet-based transducer technology. Many different types of sensors have been developed which suit particular purposes. In certain magnetic sensors, the magnetically-sensitive component must be positioned accurately during an active calibration so the output signals from the sensor are precisely responsive to the position of the gear tooth, notwithstanding the possible variation in magnetic field strength and the uniformity of the magnetic field provided by the magnet.

An example of a magnetic sensor is the magnetic sensor disclosed in U.S. Pat. No. 5,596,272 to Busch, which describes a magnetic sensor with a beveled permanent magnet. The beveled surface intersects a first pole face at a pre-selected angle. The permanent magnet is associated with a magnetically-sensitive component that comprises first and second magnetoresistive elements. Both of the magnetoresistive elements comprise two magnetoresistors. The four magnetoresistors are connected in electrical communication with each other to form a Wheatstone bridge that provides an output signal representative of the magnetic field strength in the sensing plane of the magnetically-sensitive component. The beveled magnet thus provides a magnetic field, which relates to a magnetically-sensitive component in such a manner that the position of a magnetic null in the sensing place is advantageously affected.

An example of another magnetic sensor is disclosed in U.S. Pat. No. 5,729,128 to Bunyer et al., which discloses a magnetic sensor comprising a permanent magnet, which has a first pole face and a second pole face. The first and second pole faces are generally perpendicular to an axial centerline, which extends along the central axis of the permanent magnet. A channel is formed in the permanent magnet in a direction along the centerline. Molding a magnet in a shape, which has a generally U-shaped cross section, can form the channel.

Regardless of the specific type of magnetic sensor used, certain characteristics are important to the operation of the sensor. One of the most important characteristics of the magnetic sensor is the distinctiveness of its output signal with regard to the presence and absence of a ferromagnetic object in the detection zone. For example, a very slight change in the magnitude of the sensor's output signal could possibly create difficulty in the precise identification of the leading edge of the ferromagnetic object as it moves past the face of the sensor. In many automotive applications, it is necessary for the sensor to be able to accurately and precisely identify the location of the ferromagnetic object as it moves through the detection zone. In common applications of magnetic sensors that are used as gear tooth sensors, the ferromagnetic objects that move through the detection zone are the teeth of a rotatable gear.

In the manufacture of some magnetic sensors, it is important to calibrate the sensor so it provides a predictable signal when placed in a particular position relative to a ferromagnetic object, such as a gear tooth. In automotive applications, it is particularly important to calibrate the sensor so it reacts predictably with a pre-selected signal of known magnitude when an edge of a gear tooth passes through a certain position within the detecting zone of the sensor. If the sensor is not properly calibrated, it can provide its output signal in either a premature or delayed manner and, therefore, may not be useable in association with automotive engines, which require precise timing signals.

Current magnetic sensor calibration methods involve one of two forms of calibration. The first form of calibration involves moving the magnet relative to the sensing elements. Moving the magnet requires a package design that is relatively complex compared to an assembly without moving parts. The second form of calibration involves electronically calibrating the device, such as diode zapping on an integrated circuit. Present calibration methods utilize either electronic zap techniques or moving the magnet that cancel the combined offsets of electronic and magnetic systems altogether. Because the electronic and magnetic system temperature variations are different from one another, the resulting calibration is adequate only at the temperature at which the calibration was conducted. The present inventors have thus concluded, based on the foregoing, that a need exists for a magnetic sensor calibration method and system which can overcome the problems associated with prior art calibration methods. To that end, a unique calibration method and system is disclosed and claimed herein.

### BRIEF SUMMARY OF THE INVENTION

The following summary of the invention is provided to facilitate an understanding of some of the innovative features unique to the present invention and is not intended to be a full description. A full appreciation of the various aspects of the invention can be gained by taking the entire specification, claims, drawings, and abstract as a whole.

It is, therefore, one aspect of the present invention to provide an improved magnetic sensor.

It is another aspect of the present invention to provide improved magnetic sensors that utilize magnetically-sensitive components to sense the presence or absence of ferromagnetic objects in a detection zone.

It is an additional aspect of the present invention to provide methods and systems for calibrating a magnetic sensor.

It is yet another aspect of the present invention to provide methods and systems for calibrating magnetic sensors, such as, for example, gear tooth sensors or wheelspeed sensors, which may be utilized in automotive applications.

It is still another aspect of the present invention to provide methods and systems for calibrating magnetic sensors by calibrating magnetic components separately from electronic components associated with such magnetic sensors.

The above and other aspects are achieved as is now described. A method and system for calibrating a magnetic sensor having a magnet and a sensing element incorporated therein is disclosed herein. A magnetization direction of the magnet is altered in at least one axis until the sensing element is balanced. The alternative method of moving the magnet is more costly. The magnet can be calibrated separately from the electronic components associated with the magnetic sensor to thereby achieve an improved calibration over temperature variations associated with the magnetic sensor. The magnetic sensor can be configured to include one or more magnets and one or more sensing elements. Such magnets may be calibrated according to the methods and systems disclosed herein, in association with such sensing elements.

As utilized herein, the term “sensing element” refers to one or more sensing components configured in such a manner as to comprise a single output. Some examples of sensing elements are: a single Hall element; two Hall elements with the output being the difference between the two; four magnetoresistive elements in a Wheatstone bridge configuration, etc. A balanced sensing element can be achieved when the output is zero or may also refer to an output at a predefined level other than zero. In either case, the balanced sensing element is advantageous from a signal processing or performance over temperature perspective.

Each magnet may be calibrated separately from the electronics associated with the magnetic sensor. The magnetization direction of the magnet may be altered in one or more axis until the sensing element is balanced. The magnetic sensor may, for example, comprise a gear tooth sensor or a wheelspeed sensor. Additionally, the magnetic sensor can be electronically calibrated prior to the magnet calibration utilizing at least one electronic component, such as, for example, a diode zap.

The present invention thus describes a method and system for calibrating gear tooth sensors and wheelspeed sensors of the type wherein a magnet and sensing elements are packaged into a sensor to determine transitions from tooth to slot of a rotating ferrous gear. These devices can require calibration of the magnet to the sensing elements. Current methods involve one of two forms of calibration, which may include either moving the magnet relative to the sensing elements or electronically calibrating the device, such as diode zapping on an integrated circuit. The present invention thus calibrates by changing the magnetization direction of the magnet in one or two axes until the sensing elements are balanced.

Present calibration methods utilize either electronic zap techniques or moving the magnet that cancel the combined offsets of electronic and magnetic systems altogether. Because the electronic and magnetic system temperature variations are different, the calibration is good at only the temperature at which the calibration was conducted. The present invention calibrates the magnetics separately from the electronics, and this, combined with an electronics calibration (e.g., such as diode zap), will provide a better calibration over temperature variations.

### BRIEF DESCRIPTION OF THE DRAWINGS

The accompanying figures, in which like reference numerals refer to identical or functionally-similar elements throughout the separate views and which are incorporated in and form part of the specification, further illustrate the present invention and, together with the detailed description of the invention, serve to explain the principles of the present invention.

FIG. 1 illustrates a prior art magnetic sensor made in accordance with principles known to those skilled in the art;

FIG. 2 depicts a conventional Wheatstone bridge arrangement of magnetoresistors;

FIG. 3 illustrates a magnet before calibration, in accordance with a preferred embodiment of the present invention;

FIG. 4 depicts a magnet after calibration, in accordance with a preferred embodiment of the present invention;

FIG. 5 illustrates a flow chart of operations illustrating operational steps for calibrating a magnetic sensor, in accordance with a preferred embodiment of the present invention; and

FIG. 6 depicts a flow chart illustrating operational steps for calibrating a magnetic sensor, in accordance with an alternative preferred embodiment of the present invention.

### DETAILED DESCRIPTION OF THE INVENTION

The particular values and configurations discussed in these non-limiting examples can be varied and are cited merely to illustrate an embodiment of the present invention and are not intended to limit the scope of the invention.

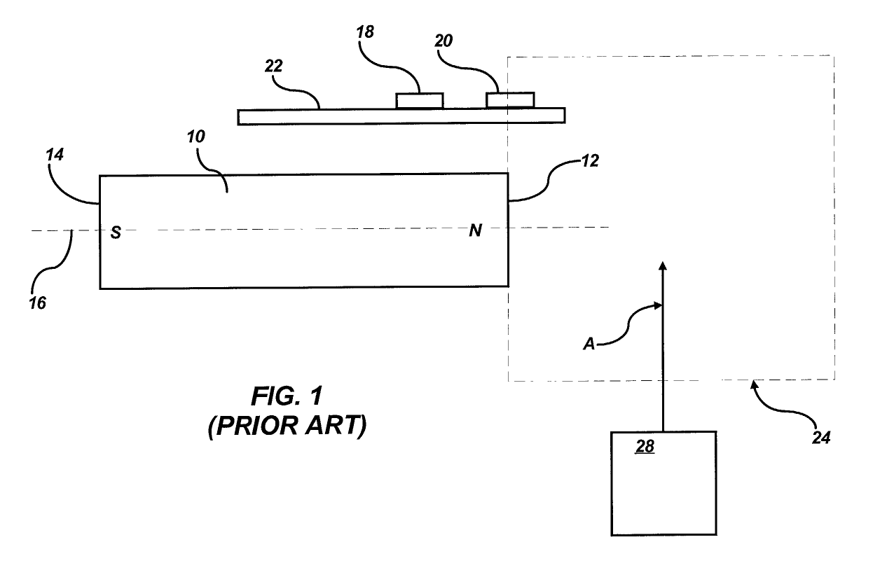

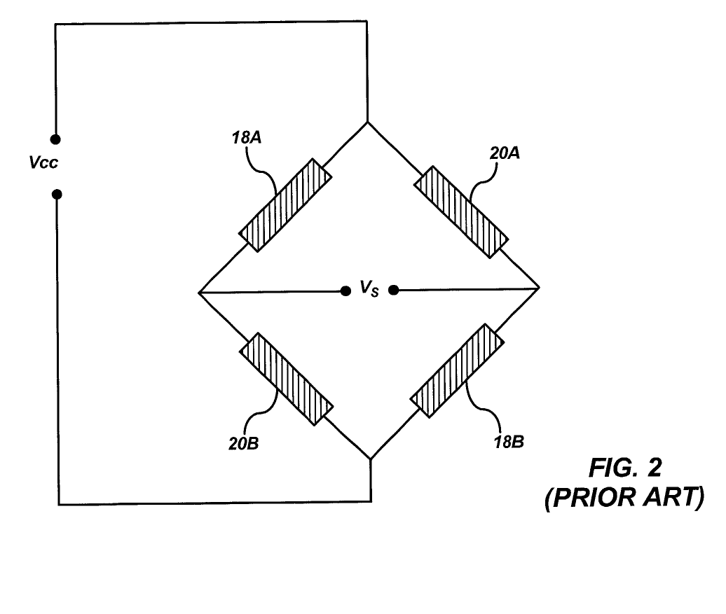

Before describing the beneficial effects that result from the magnetic sensor calibration methods and systems of the present invention it is helpful to understand information about types of magnetic sensors in which the present invention may be implemented. The configurations depicted in FIGS. 1 and 2 are presented for edification purposes only and should not be interpreted as limiting the scope of the present invention.

FIG. 1 thus illustrates a prior art configuration of a magnetic sensor that can be used for detection of a ferromagnetic object moving through a detection zone. Such a magnetic sensor comprises a permanent magnet 10 that has a first pole face 12 and a second pole face 14. The permanent magnet 10 has a magnetic axis 16 that extends through the planes of the first and second pole faces. In the illustrative sensor depicted in FIG. 1, a magnetically-sensitive component, which comprises two magnetoresistive elements, 18 and 20, is disposed proximate a lateral surface of the permanent magnet 10 and in a sensing plane that is generally parallel to the magnetic axis 16. The magnetically-sensitive component (18, 20) is disposed on a substrate 22. Although the relative positions of the magnetically-sensitive component and the permanent magnet 10 can vary in possible configurations of the sensor, one potential configuration may dispose the first and second magnetoresistive elements, 18 and 20, at a position where the plane of the first pole face 12 intersects one of the magnetically sensitive elements.

With continued reference to FIG. 1, a dashed line box 24 represents a detection zone through which a ferromagnetic object 28 can pass in the direction represented by arrow A. When the ferromagnetic object 28 moves through the detection zone 24, its presence within the zone distorts the magnetic field provided by the permanent magnet 10. The magnetically-sensitive component senses the magnitude of the magnetic field in the sensing plane of the first and second magnetoresistive elements and provides an output signal that is representative of that magnitude of magnetic field. Changes in the output signal from the magnetically-sensitive component can be detected to determine the present or absence of the object 28 in the detection zone.

FIG. 2 illustrates a known arrangement of magnetoresistors. FIG. 2 is helpful to understand the type of signals that can be provided by magnetically-sensitive components. In FIG. 2, four magnetoresistors, 18A, 18B, 20A and 20B, are connected in electrical communication with each other to form a Wheatstone bridge arrangement. A single magnetoresistive element may comprise two magnetoresistors 18A and 18B. Similarly, another single magnetoresistive element may comprise magnetoresistors 20A and 20B. Magnetoresistors 18A and 18B can be arranged in a nested serpentine pattern to form a single magnetoresistive element. Similarly, magnetoresistors 20A and 20B can also be configured in a nested serpentine pattern to form a single magnetoresistive element. If a voltage V_{CC} is connected as illustrated in FIG. 2, an output voltage V_{S} will reflect changes in the resistance of the magnetoresistors in response to changes in the magnitude of the magnetic field that extends within the sensing plane of the magnetically-sensitive component. The arrangement of magnetoresistors depicted in FIG. 2 is thus presented for edification purposes only and is not considered a limiting feature of the present invention. Other types of magnet sensor arrangements, such as Hall configuration arrangements, may be implemented in accordance with the calibration methods and systems of the present invention.

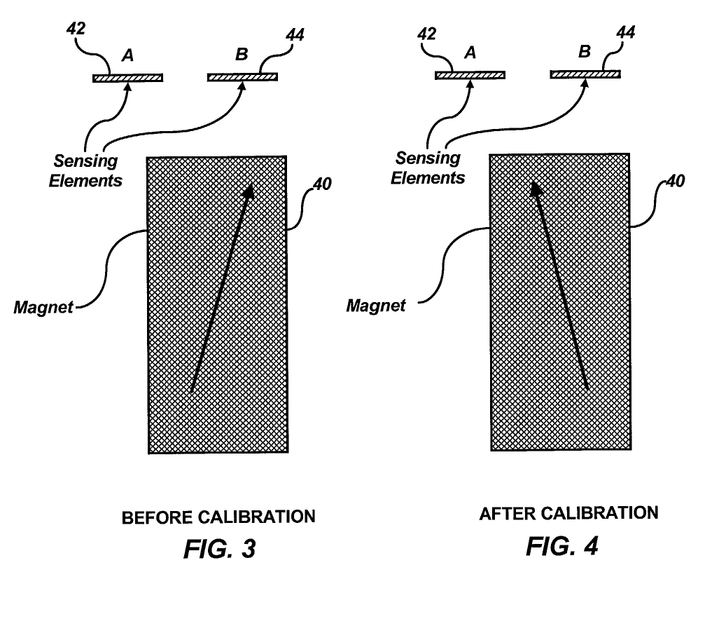

FIG. 3 illustrates a magnet 40 before calibration, in accordance with a preferred embodiment of the present invention. FIG. 4 depicts magnet 40 after calibration, in accordance with a preferred embodiment of the present invention. Note that in FIGS. 3 and 4 like parts are indicated by identical reference numerals. Sensing elements 42 and 44 may be configured within a sensor assembly of a magnetic sensor. Note that the arrow illustrated in FIGS. 3 and 4, which is superimposed upon magnet 40 indicates the direction of magnetization. The arrow is thus illustrative in different directions in FIGS. 3 and 4.

An example of a magnetic sensor in which the present invention is implement is a gear tooth sensor. Another example of a magnetic sensor that may be calibrated according to the methods and systems disclosed herein is a wheelspeed sensor. In a gear tooth sensor, for example, an output signal can be provided, which is responsive to the movement of ferromagnetic teeth of a gear through a detection zone located generally proximate a pole face of a magnet, such as magnet 40. The magnetic sensor associated with sensing elements 42 and magnet 40 can be implemented in association with automobile engines to provide signals that are responsive to the rotation of certain engine components. These signals are utilized by engine control systems. Thus, in a magnetic sensor assembly that includes magnet 40 and sensing elements 42 and 44 and magnet 40 can be packaged into a sensor package that can detect transitions from tooth to slot of a rotating ferrous gear.

A sensor assembly may include one or more sensing elements (e.g., sensing elements 42 and 44) or two halves to each of the sensing elements, wherein an analog signal is output from the sensing elements. As utilized herein, a “sensing element” can refer to one or more sensing components configured in such a manner as to comprise a single output. Some examples of sensing elements are: a single Hall element; two Hall elements with the output being the difference between the two; four magnetoresistive elements arranged in a Wheatstone bridge configuration, and the like. A balanced sensing element can be achieved when the output is zero, or an output at a predefined level other than zero. In either case, the balanced sensing element is advantageous from a signal processing or performance over temperature perspective.

Some sensor assemblies require calibration of the magnet to the sensing elements so that the sensing elements are balanced. Current methods involve one or two forms of calibration, including either moving the magnet relative to the sensing elements or electronically calibrating the device, such as “diode zapping” on an integrated circuit. Diode zapping techniques have been widely used as a method for controlling variations in analog integrated circuits etc. caused in manufacture after the manufacture so as to generate highly accurate voltage. A type of diode typically utilized in diode zapping operations is a Zener diode. The calibration methods and systems disclosed and claimed herein essentially alter the magnetization direction of the magnet in one or two axes until the sensing elements (e.g., sensing elements 42 and 44) are balanced.

Magnet 40 can thus act as a biasing magnet incorporated within a magnetic sensor. Such a biasing magnet is associated with a magnetically-sensitive component, such as sensing elements 42 and 44. Sensing elements 42 and 44 may comprise, for example, a magnetoresistive element or a Hall effect element. A magnetic sensor associated with magnet 40 and sensing elements 42 and 44 thus respond to a change in the magnetic field provided by the permanent magnet (i.e., magnet 40) when a ferromagnetic object moves into an associated detection zone. When magnetic sensors of this types are mass produced, the relative position between magnet 40 and sensing elements 42 and 44 are often accurately controlled so that ferromagnetic objects can be detected in an identical manner, regardless of the particular type of sensor utilized. Also, sometimes a calibration process is needed to meet performance requirements.

Magnet 40 can be configured according to a permanent magnet structure that includes a permanent magnet and a pole piece disposed on a pole face of the permanent magnet. The pole piece can be composed of any suitable ferromagnetic material. It should be understood, however, that such a pole piece is not a limiting feature of the present invention and, further, is not a required element in all embodiments of the present invention. The pole piece is mentioned herein only for general edification purposes.

Additionally, sensing elements 42 and 44, which comprise magnetically-sensitive components, can be configured in association with individual chips. The individual chips can, in turn, comprise an integrated circuit chip and one or more separate sensor chips. The sensor chips can be magnetoresistive. Alternatively, the sensor chips may comprise Hall effect elements or indium antimonide elements. The particular material utilized to provide the magnetic sensitivity is not a limiting feature of the present invention.

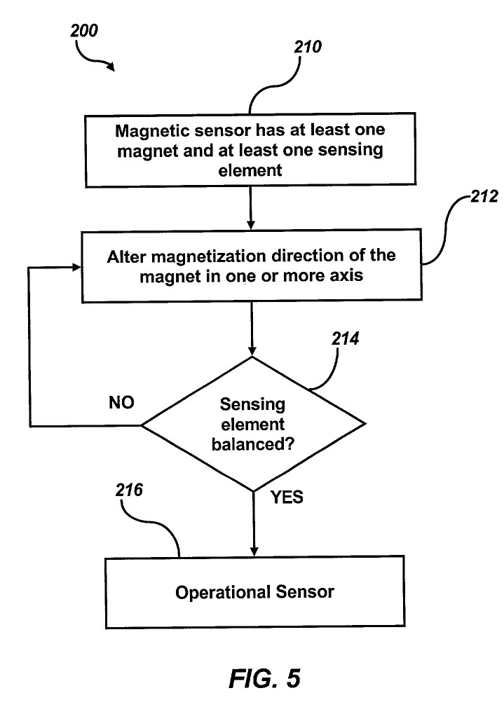

FIG. 5 illustrates a flow chart 200 of operations illustrating operational steps for calibrating a magnetic sensor, in accordance with a preferred embodiment of the present invention. As indicated at block 210, a magnet sensor to be calibrated generally includes at least one magnet, such as magnet 40 of FIGS. 3 and 4, and at least one sensing element, such as sensing elements 42 and/or 44 of FIGS. 3 and 4. As illustrated at block 212, the magnetization direction of the magnet (e.g., magnet 40) is altered in one or more axis until the sensing elements (e.g., sensing elements 42 and 44) are balanced. Thus, as illustrated at block 214, a test can be performed to determine whether or not the sensing elements are balanced. If not, the operational step illustrated at block 212 is repeated until balancing is achieved. If so, the process continues, as illustrated next at block 216, in which the sensor is now operational.

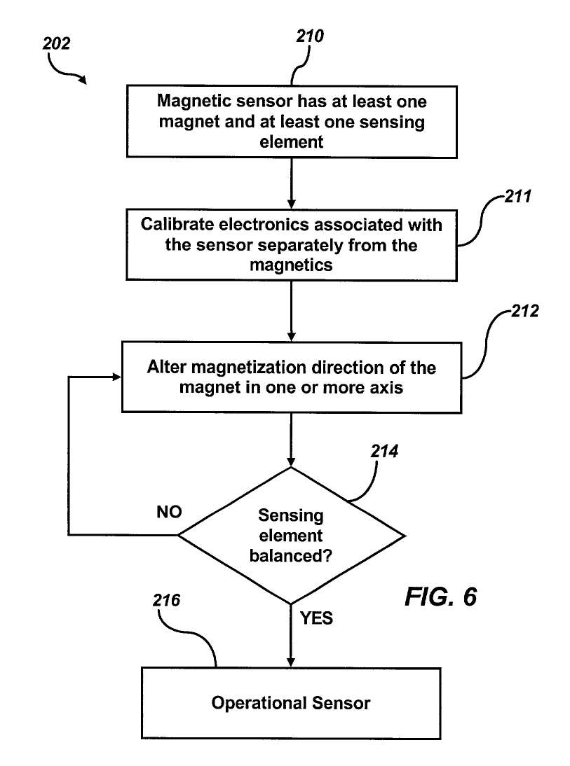

FIG. 6 depicts a flow chart 202 illustrating operational steps for calibrating a magnetic sensor, in accordance with an alternative preferred embodiment of the present invention. Note that in FIGS. 5 and 6, analogous elements, parts, or operational steps are indicated by identical reference numerals. Thus, as indicated In FIG. 6 at block 210, a magnet sensor to be calibrated generally includes at least one magnet, such as magnet 40 of FIGS. 3 and 4, and at least one sensing element, such as sensing elements 42 and/or 44 of FIGS. 3 and 4. Next, as indicated at block 211, electronic components associated with the sensor can be calibrated separately from the magnetics. This operation can be accomplished without the magnet(s) present; or if the magnet or magnets are present, such magnets should be unmagnetized, and thereafter magnetized during or prior to processing of the magnet calibration loop (i.e., blocks 212 and 214).

As illustrated at block 212, the magnetization direction of the magnet (e.g., magnet 40) can be altered in one or more axis until the sensing elements (e.g., sensing elements 42 and 44) are balanced. As depicted thereafter at block 214, a test can be performed to determine whether or not the sensing elements are balanced. If not, then the operational step illustrated at block 212 is repeated until balancing is achieved. If so, then the process continues, as indicated next at block 216. The operational steps illustrated in FIG. 6 thus indicate calibration of the magnetics separately from the electronics, combined with, for example, an electronics calibration component, such as a zap diode, can achieve an improved calibration over temperature variations.

The present invention thus describes a method and system for calibrating a magnetic sensor having a magnet and a sensing element incorporated therein. A magnetization direction of the magnet can be altered in at least one axis until the sensing element is balanced. The magnet can be calibrated separately from the electronic components associated with the magnetic sensor to thereby achieve an improved calibration over temperature variations associated with the magnetic sensor. The magnetic sensor can be configured to include one or more magnets and one or more sensing elements. Such magnets may be calibrated according to the methods and systems disclosed herein, in association with such sensing elements.

Each magnet can be calibrated separately from the electronics associated with the magnetic sensor. The magnetization direction of the magnet can be altered in one or more axis until the sensing element is balanced. The magnetic sensor may, for example, comprise a gear tooth sensor or a wheelspeed sensor. Additionally, two basic elements can compose a calibration system, in accordance with one or more embodiments of the present invention. These elements or features are essentially a directional mechanism for altering a magnetization direction of the magnet in at least one axis until the sensing element is balanced; and a calibration mechanism for calibrating the magnet separately from electronics associated with the magnetic sensor to thereby achieve an improved calibration over temperature variations associated with the magnetic sensor.

Based on the foregoing, it can be appreciated that two aspects of the present invention are illustrated and claimed herein. First, calibration may be achieved by altering the magnetization direction of the magnet until the output of the sensing element(s) attains a predetermined level. This first type of calibration can be performed in a device after assembly of the appropriate electronic and magnetic components. Such a calibration feature may be implemented in a preferred embodiment of the present invention.

Second, as explained previously, electronic calibration techniques and devices thereof may be utilized to achieve calibration. Electronic calibration can thus be achieved through electronic techniques, such as diode zap, laser trim, and so forth. Electronic calibration can be performed to properly bias the electronics. Electronic calibration can be performed prior to the assembly of appropriate electronic and magnetic components, followed by calibration in which the magnetization direction of the magnet is altered until the output of the sensing element(s) attains a predetermined level. Such a calibration technique may be implemented via a preferred embodiment of the present invention.

Alternatively, electronic calibration can be performed prior to the assembly of appropriate electronic and magnetic components, followed by calibration in which the magnet is moved relative to the sensing element(s) until the output of the sensing element attains a predetermined level. Alternatively, electronic calibration may be performed before or after the assembly of the appropriate electronic and magnetic components, with or without any subsequent magnetic calibration.

If the output of an electronic amplifier is nominally zero (e.g., or any predetermined value) output with zero input in an electronic calibration scenario, but upon manufacturing of a given device, it is not zero but contains some offset, a diode zap can be utilized to eliminate such offset. If the magnetics are not calibrated, then the electronics calibration techniques described herein could be utilized after the appropriate magnetic and electronic components are assembled. The offset due to magnet mis-position (or a wrong magnetization angle) along with electronic offset can be calibrated out via electronic calibration. The magnetic offset and the electronic offset, however, are likely to possess different temperature coefficients and, thus, the calibration would not hold over temperature variation. This is true because the electronics can be configured to track one temperature coefficient, but it cannot track two such temperature coefficients.

The sensing elements described herein can be arranged as a single sensing element (e.g., a Hall element), or as two sensing elements (e.g., two Halls in a differential mode). Additionally, the sensing elements can be configured as four sensing elements in a Wheatstone bridge configuration (e.g., utilizing magnetoresistive sensing elements). The sensing elements may also be configured in an arrangement of multiple sensing elements. Each of the aforementioned configurations may be implemented in one or more preferred embodiments of the present invention. The nominal orientation and position of the sensing element(s) relative to the magnet is application specific and thus the present invention described herein does not preclude any modifications or other possibilities in that regard.

Depending on a particular implementation of the present invention, a device can be constructed in which no calibration is necessary; however, the manufacturing cost associated with the better part tolerances required to achieve a given level of performance may make it more expensive than calibration. So, calibration is often the least expensive path to take to achieve the desired performance. For some applications with loose specifications, however, no calibration may suffice to meet performance criteria. Thus, calibration improves performance, but may potentially increase cost.

The purpose of such calibration aspects can be to bias the sensor in a range where it will operate, limit part-to-part variation, and/or reduce sensor operational variation over temperature. This usually involves calibrating the appropriate sensing element(s) output and/or electronics output to a zero value to thereby reduce the effect of scale factor temperature effects.

Calibration, according to the methods and systems of the present invention may take place without a gear target, with the gear target at a specific position or with a spinning target, depending on a particular implementation of the present invention. The best performance can be achieved by calibrating a device with the gear target. This may, however, add to manufacturing cost.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered. The description as set forth is not intended to be exhaustive or to limit the scope of the invention. Many modifications and variations are possible in light of the above teaching without departing from the scope of the following claims. It is contemplated that the use of the present invention can involve components having different characteristics. It is intended that the scope of the present invention be defined by the claims appended hereto, giving full cognizance to equivalents in all respects.

The embodiments of the invention in which an exclusive property or right is claimed are defined as follows:

1. A method for calibrating a magnetic sensor having a magnet and a sensing element incorporated therein, said method comprising the step of:
altering a magnetization direction of said magnet in at least one axis until said sensing element is balanced.

2. The method of claim 1 further comprising the step of:
calibrating electronics associated with said magnetic sensor separately from said magnet to thereby achieve an improved calibration over temperature variations associated with a magnetic sensor value.

3. The method of claim 1 further comprising the step of:
configuring said magnetic sensor to include at least one magnet and at least one sensing element therein, such that a magnetization direction of said at least one magnet is altered in said at least one axis until said at least one sensing element is balanced.

4. The method of claim 1 wherein the step of altering a magnetization direction of said magnet in at least one axis until said sensing element is balanced, further comprises the step of:
altering a magnetization direction of said magnet in two axes until said sensing element is balanced.

5. The method of claim 1 wherein said magnetic sensor comprises a gear tooth sensor.

6. The method of claim 1 wherein said magnetic sensor comprises a wheelspeed sensor.

7. The method of claim 1 further comprising the step of:
configuring said magnetic sensor to include a sensor assembly comprising at least two sensing elements.

8. The method of claim 1 wherein said sensing element comprises a magnetoresistive-sensing element.

9. The method of claim 1 further comprising the step of:
configuring said magnetic sensor according to a differential Hall configuration.

10. The method of claim 1 further comprising the step of:
configuring said magnetic sensor according to a Wheatstone bridge configuration.

11. The method of claim 1 further comprising the step of:
electronically calibrating said magnetic sensor utilizing at least one electronic calibration component.

12. The method of claim 11 wherein the step of electronically calibrating said magnetic sensor utilizing at least one electronic calibration component, further comprises the step of:
electronically calibrating said magnetic sensor utilizing at least one electronic calibration component, wherein said at least one electronic calibration component comprises a diode zap.

13. The method of claim 1 wherein the step of altering a magnetization direction of said magnet in at least one axis until said sensing element is balanced, further comprises the step of:
altering a magnetization direction of said magnet until an output of said sensing element attains a predetermined level.

14. A method for calibrating a magnetic sensor having a magnet and a sensing element incorporated therein, said method comprising the steps of:
altering a magnetization direction of said magnet in at least one axis until said sensing element is balanced; and
configuring said magnetic sensor to include at least one magnet and at least one sensing element therein, such that a magnetization direction of said at least one magnet is altered in said at least one axis until said at least one sensing element is balanced.

15. A method for calibrating a magnetic sensor having a magnet and a sensing element incorporated therein, said method comprising the steps of:
altering a magnetization direction of said magnet in at least one axis until said sensing element is balanced, wherein said sensing element comprises a magnetoresistive sensing element;
configuring said magnetic sensor to include a sensor assembly comprising at least two sensing elements; and
calibrating electronics associated with said magnetic sensor separately from said magnet to thereby achieve an improved calibration over temperature variations associated with a magnetic sensor value.

16. A system for calibrating a magnetic sensor having a magnet and a sensing element incorporated therein, said system comprising:
the magnet having a magnetization direction altered in at least one axis until said sensing element is balanced;
wherein said magnetic sensor comprises at least one magnet and at least one sensing element therein, such that a magnetization direction of said at least one magnet is altered in said at least one axis until said at least one sensing element is balanced.

17. The system of claim 16 further comprising electronics associated with said magnet, wherein electronics associated with said magnetic sensor are calibrated separately from said magnet to thereby achieve an improved calibration over temperature variations associated with a magnetic sensor value.

18. The system of claim 16 wherein said magnetization direction of said magnet is altered in two axes until said sensing element is balanced.

19. The system of claim 16 wherein said magnetic sensor comprises a gear tooth sensor.

20. The system of claim 16 wherein said magnetic sensor comprises a wheelspeed sensor.

21. The system of claim 16 wherein said magnetic sensor includes a sensor assembly comprising at least two sensing elements.

22. The system of claim 16 wherein said sensing element comprises a magnetoresistive-sensing element.

23. The system of claim 16 wherein said magnetic sensor is configured according to a differential Hall configuration.

24. The system of claim 16 wherein said magnetic sensor is configured according to a Wheatstone bridge configuration.

25. The system of claim 16 wherein said magnetic sensor is electronically calibrated utilizing at least one electronic calibration component.

26. The system of claim 25 wherein said at least one electronic calibration component comprises a diode zap.

27. The system of claim 16 wherein said magnetization direction of said magnet is altered until an output of said sensing element attains a predetermined level.

28. A system for calibrating a magnetic sensor having a magnet and a sensing element incorporated therein, said system comprising the steps of:
a magnetization direction of said magnet altered in at least one axis until said sensing element is balanced; and
wherein said magnetic sensor is configured to include at least one magnet and at least one sensing element therein, such that a magnetization direction of said at least one magnet is altered in said at least one axis until said at least one sensing element is balanced.
